(19) United States
(12) Patent Application Publication
(10) Pub. No.: US 2017/0243766 A1
(43) Pub. Date: Aug. 24, 2017

(54) MINIATURE WAFER PROCESSING APPARATUS

(71) Applicants: Yi-Cheng WANG, Hsinchu (TW); WET Technology Co., Ltd., Hsinchu (TW)

(72) Inventor: Yi-Cheng WANG, Hsinchu (TW)

(21) Appl. No.: 15/046,879

(22) Filed: Feb. 18, 2016

(51) Int. Cl. H01L 21/67

(52) U.S. Cl. CPC H01L 21/67075

(57) ABSTRACT

A miniature wafer processing apparatus includes a first half portion, a second half portion, a gas supply unit, a liquid supply unit, a ring sealing member disposed at peripheries of the first half portion and the second half portion, and a liquid recycling member. The first half portion includes a first hole disposed at a work platform. The second half portion includes an upper cover correspondingly covering the work platform to form a processing chamber, and a second hole disposed at the upper cover. The gas supply unit and the liquid supply unit are in communication with the first hole and the second hole. The liquid recycling member includes a recycling tube, a discharging tube and a filtering portion. With the first half portion and the second half portion, the processing chamber and the overall volume can be reduced.

### FIELD OF THE INVENTION

The present invention relates to a semiconductor processing apparatus, and particularly to a miniature wafer processing apparatus.

### BACKGROUND OF THE INVENTION

A wafer is a piece of silicon utilized for manufacturing silicon semiconductor integrated circuits, and integrated circuits are manufactured thereon. The manufacturing process of integrated circuits involve tens or even hundreds of steps, such as lithography, etching and chemical deposition. When these steps are performed, a wafer is usually placed in a processing apparatus and separated from the exterior, so as to increase the yield rate of the manufacturing process and to prevent hazardous materials generated in the manufacturing process from leaking.

For example, the U.S. Pat. No. 8,333,842 discloses “Apparatus for Etching Semiconductor Wafers”. The apparatus includes a chamber, a showerhead disposed at a top region of the chamber, and a wafer pedestal disposed at a bottom region of the chamber. The chamber defines a processing region. A wafer is placed on the wafer pedestal and is located in the processing region. During a manufacturing process, the showerhead processes the wafer.

However, a large gap is present between the top region and the bottom region of the chamber, in a way that the volume of the chamber is large and the volume of the overall apparatus is also increased. Therefore, it is a task as how to reduce the volume of a wafer processing apparatus and to increase space utilization efficiency.

### SUMMARY OF THE INVENTION

The primary object of the present invention is to solve the issue of a reduced space utilization efficiency caused by a large volume of a wafer processing apparatus.

To achieve the above object, the present invention provides a miniature wafer processing apparatus for processing a wafer. The miniature wafer processing apparatus includes a first half portion, a second half portion disposed above the first half portion, a gas supply unit, a liquid supply unit, a ring sealing member and a liquid recycling member. The first half portion includes a work platform, and a first hole disposed at the work platform. The second half portion includes an upper cover correspondingly covering the work platform to form a processing chamber for accommodating the wafer, a second hole disposed at the upper cover, and a lifting member connected to the upper cover. The gas supply unit is in communication with the first hole and the second hole, and provides a gas to the processing chamber. The liquid supply unit is in communication with the first hole and the second hole, and provides a liquid to the processing chamber. The ring sealing member is disposed at peripheries of the first half portion and the second half portion. The liquid recycling member includes a recycling tube penetrating through the ring sealing member and being in communication with the processing chamber, a discharging tube, and a filtering portion in communication with the recycling tube and the discharging tube.

In conclusion, the present invention provides following features.

1. The processing chamber slightly larger than the wafer is formed by correspondingly covering the work platform with the upper cover. Thus, the processing chamber is reduced to further reduce the volume of the miniature wafer processing apparatus and to increase space utilization efficiency

2. The recycling tube is in communication with the discharging tube and the processing chamber. Thus, the liquid having entered the processing chamber can be recycled, filtered by the filtering portion, and again inputted into the processing chamber via the discharging tube. Therefore, the liquid can be recycled and reused for lower costs.

### BRIEF DESCRIPTION OF THE DRAWINGS

FIG. 1 is a sectional structure view according to a first embodiment of the present invention;

FIG. 2A to FIG. 2C are schematic diagrams of continuous operations according to the first embodiment of the present invention;

FIG. 3 is a sectional structure view according to a second embodiment of the present invention; and

FIG. 4 is a schematic diagram illustrating a discharging mechanism according to the second embodiment of the present invention.

### DETAILED DESCRIPTION OF THE PREFERRED EMBODIMENTS

Details and technical contents of the present invention are given with the accompanying drawings below.

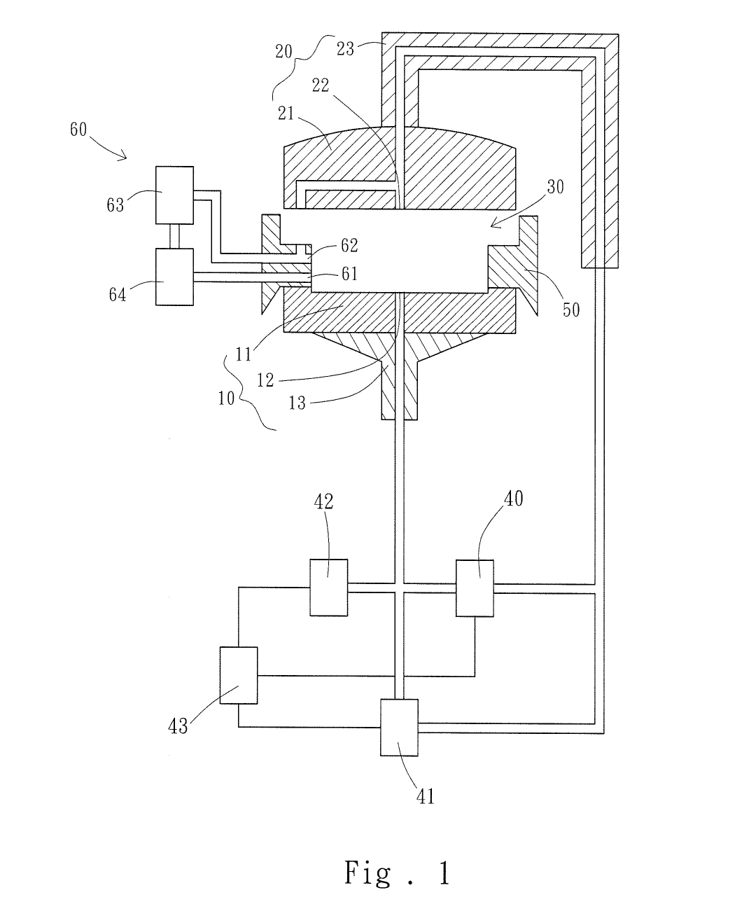

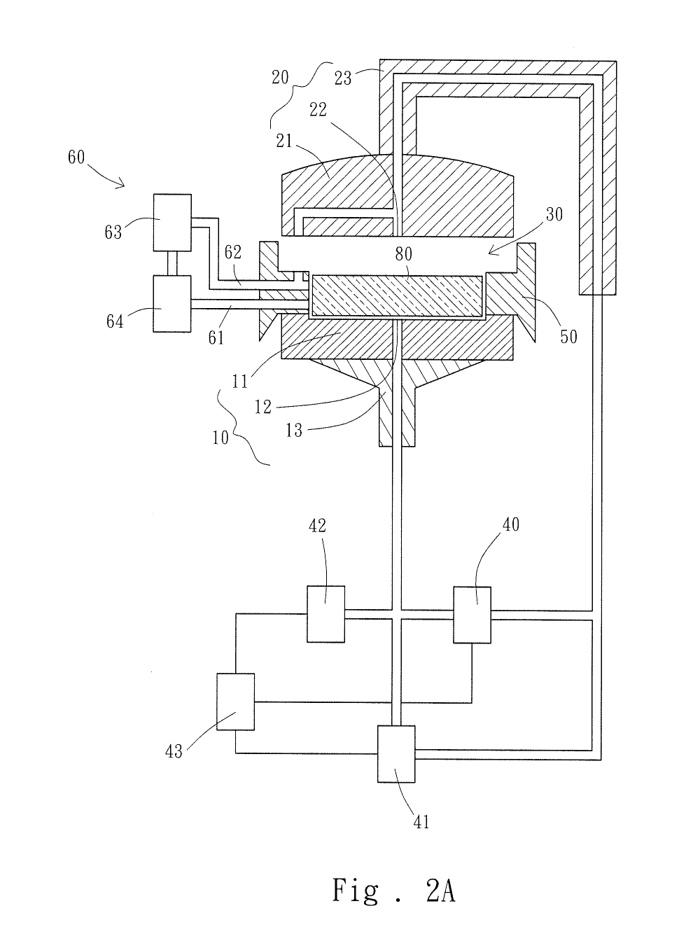

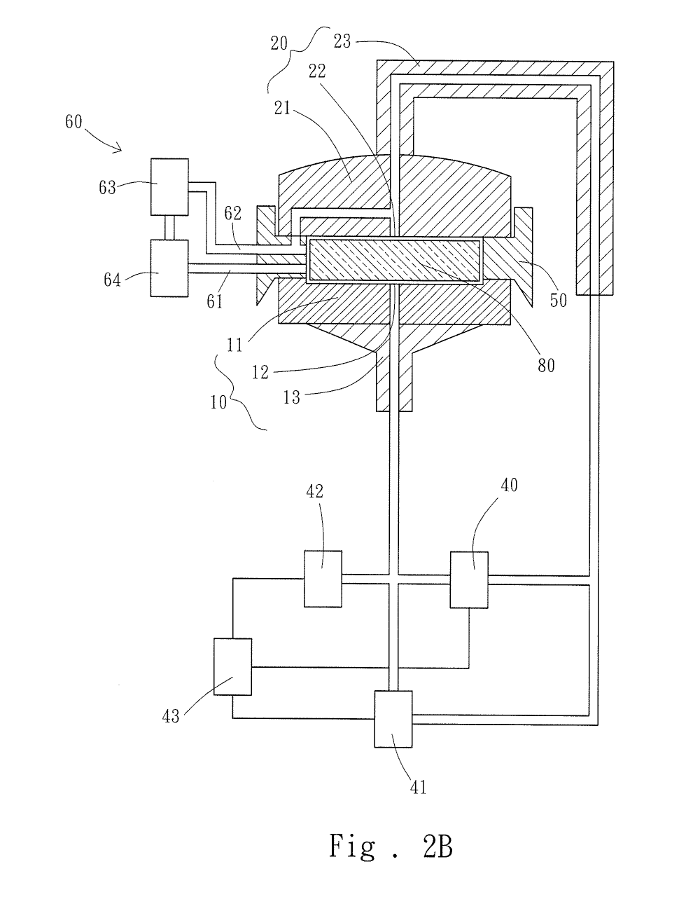

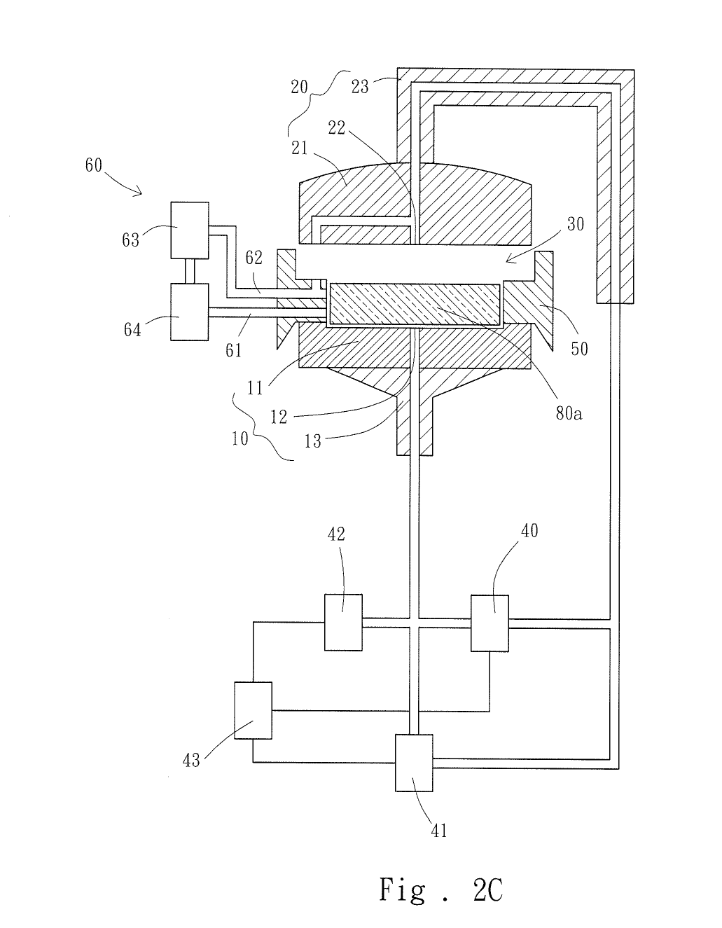

FIG. 1 and FIG. 2A to FIG. 2C are a sectional structural view and schematic diagrams of continuous operations according to a first embodiment of the present invention. Referring to FIG. 1 and FIG. 2A to FIG. 2C, the present invention provides a miniature wafer processing apparatus that processes a wafer 80. The miniature wafer processing apparatus includes a first half portion 10, a second half portion 20 disposed above the first half portion 10, a gas supply unit 40, a liquid supply unit 41, a ring sealing member 50, and a liquid recycling member 60. The first half portion 10 includes a work platform 11, and a first hole 12 disposed on the work platform 11. The second half portion 20 includes an upper cover 21 correspondingly covering the work platform 11 to form a processing chamber 30 for accommodating the wafer 80, a second hole 22 disposed at the upper cover 21, and a lifting member 23 connected to the upper cover 21. By correspondingly covering the work platform 11 with the upper cover 21, the processing chamber 30 slightly larger than the wafer 80 is formed. Thus, the processing chamber 30 can be reduced to further reduce the volume of the miniature wafer processing apparatus and to increase space utilization efficiency.

The gas supply unit 40 is in communication with the first hole 12 and the second hole 22, and provides a gas to the processing chamber 30. The liquid supply unit 41 is also in communication with the first hole 12 and the second hole 22, and provides a liquid to the processing chamber 30. In the embodiment, the gas may be air, and the liquid may be water or a chemical solution. For example, the chemical solution is a highly volatile solution having a low viscosity coefficient, e.g., isopropyl alcohol (IPA), which performs etching and cleansing processes on the wafer 80. In this embodiment, one first hole 12 and one second hole 22 are given as an example. However, the numbers of the first hole 12 and the second hole 22 may also be plural. The ring sealing member 50 is disposed at peripheries of the first half portion 10 and the second half portion 20 to prevent the liquid from leaking during an operation. The liquid recycling member 60 includes a recycling tube 61 penetrating through the ring sealing member 50 and in communication with the processing chamber 30, a discharging tube 62, a filtering portion 63 in communication with the recycling tube 61 and the discharging tube 62, and a pump 64. In this embodiment, the discharging tube 62 may also be in communication with the second hole 22.

This embodiment further includes a lifting rotating member 13 disposed at the work platform 11, a vacuum suction unit 42 in communication with the first hole 12, an a control unit 43 electrically connected to the gas supply unit 40, the liquid supply unit 41 and the vacuum suction unit 42. Associated functions and operation details are given below.

As shown in FIG. 2A to FIG. 2C, the wafer 80 to be processed is placed in the processing chamber 30. The lifting member 23 controls the upper cover 21 to ascend and descend, such that the upper cover 21 correspondingly covers the work platform 11. The control unit 43 controls the gas supply unit 40, the liquid supply unit 41 and the vacuum suction unit 42 to operate. For example, the vacuum suction unit 42 vacuum sucks the processing chamber 30, and the gas supply unit 40 or the liquid supply unit 41 then inputs the gas or the liquid via the first hole 12 and the second hole 22. Further, with the coordination of the lifting rotating member 13, the work platform 11 is controlled to rotate to proceed with the manufacturing process. Operation details of the manufacturing process may be modified according to user requirements, and are not limited to the details of the above example.

Further, the liquid for the manufacturing process may be recycled from the recycling tube 61 by the pump 64, filtered by the filtering portion 63, and again inputted into the processing chamber 30 via the discharging tube 62 or the second hole 22, thereby reusing the liquid for reduced manufacturing costs. Thus, while the manufacturing process is being performed, a half of the liquid for the processing chamber 30 may be inputted by the liquid supply unit 41, whereas the other half may be inputted by the liquid recycling member 60. That is, a half of the liquid is new, and the other half is from the recycled and filtered liquid. When the manufacturing process is complete, the lifting member 23 controls the upper cover 21 to ascend, and another wafer 80a is placed into the processing chamber 30 to perform the manufacturing process for the wafer 80a.

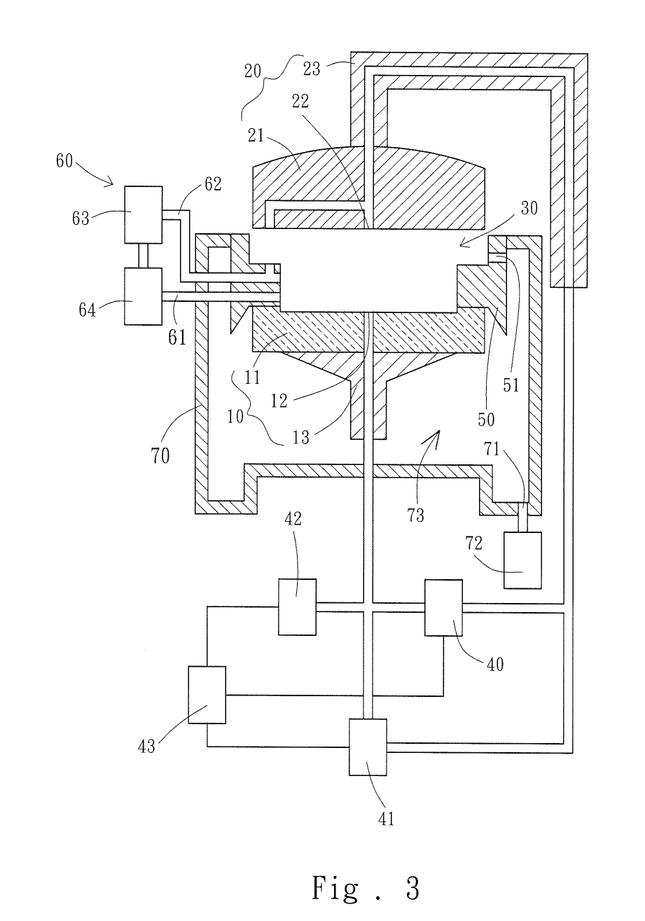

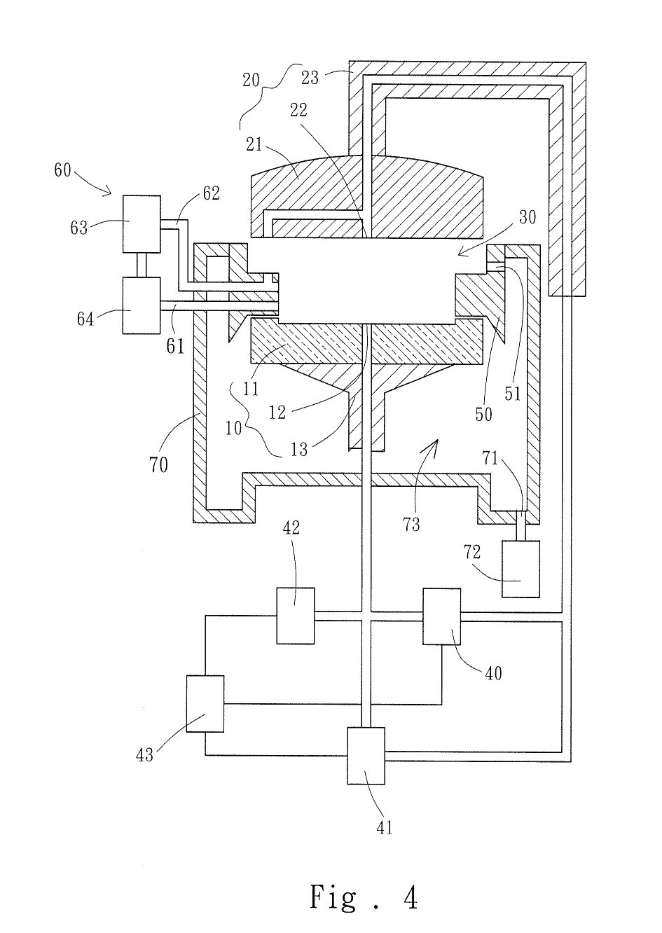

FIG. 3 and FIG. 4 are a sectional structural view and a schematic diagram illustrating a discharging mechanism according to a second embodiment of the present invention. This embodiment further includes a gas discharging opening 51 disposed on the ring sealing member 50, and discharging member 70 disposed outside the first half portion 10 and the ring sealing member 50. When cleaning is required after the manufacturing process is complete, the lifting rotating member 13 may control the work platform 11 to descend, such that a gap between the work platform 11 and the ring sealing member 50 flows to a discharging space 73 in the discharging member 70, and the gas may be discharged from the gas discharging opening 51 to the discharging space 73 and then further discharged via a discharging opening 71 in communication with the discharging space 73. The discharging opening 71 may be connected to a negative pressure device 72 to accelerate a discharging speed of the gas and the liquid. In this embodiment, one discharging opening 71 is given as an example, and the number of the discharging opening 71 may be plural in other embodiments.

In conclusion, the present invention provides following features.

1. The processing chamber slightly larger than the wafer is formed by correspondingly covering the work platform with the upper cover. Thus, the processing chamber is reduced to further reduce the volume of the miniature wafer processing apparatus and to increase space utilization efficiency.

2. By placing the ring sealing member at the peripheries of the first half portion and the second half portion, the liquid is prevented from leaking out during an operation and from resulting pollution issues.

3. With the recycling tube, the discharging tube and the filtering portion, the liquid having been used can be filtered, recycled and reused for reduced manufacturing costs.

4. The used liquid and gas are discharged to the discharging member. Thus, issues of environmental pollution and harms to humans caused by the leakage of the liquid and the gas can be minimized.

5. A negative pressure on the discharging space is generated by the negative pressure device, such that the discharging speed of the gas and the liquid can be accelerated.

What is claimed is:

1. A miniature wafer processing apparatus, for processing a wafer, the miniature wafer processing apparatus comprising:
a first half portion, comprising a work platform, and a first hole disposed at the work platform;
a second half portion, disposed above the first half portion, comprising an upper cover correspondingly covering the work platform to form a processing chamber for accommodating the wafer, a second hole disposed at the upper cover, and a lifting member connected to the upper cover;
an air supply unit, being in communication with the first hole and the second hole, providing a gas to the processing chamber;
a liquid supply unit, being in communication with the first hole and the second hole, providing a liquid to the processing chamber;
a ring sealing member, disposed at peripheries of the first half portion and the second half portion; and
a liquid recycling member, comprising a recycling tube penetrating through the ring sealing member and being in communication with the processing chamber, a discharging tube, and a filtering portion being in communication with the recycling tube and the discharging tube.

2. The miniature wafer processing apparatus of claim 1, further comprising a gas discharging opening disposed on the ring sealing member.

3. The miniature wafer processing apparatus of claim 1, wherein the first half portion further comprises a lifting rotating member disposed at the work platform.

4. The miniature wafer processing apparatus of claim 1, further comprising a vacuum suction unit in communication with the first hole.

5. The miniature wafer processing apparatus of claim 4, further comprising a control unit electrically connected to the air supply unit, the liquid supply unit and the vacuum suction unit.

6. The miniature wafer processing apparatus of claim 1, further comprising:
a discharging member, disposed outside the first half portion and the ring sealing member, comprising a discharging space for discharging the gas and the liquid, and a discharging opening in communication with the discharging space.

7. The miniature wafer processing apparatus of claim 6, further comprising a negative pressure device in communication with the discharging opening.

8. The miniature wafer processing apparatus of claim 1, wherein the gas is air.

9. The miniature wafer processing apparatus of claim 1, wherein the liquid is water or a chemical solution.

10. The miniature wafer processing apparatus of claim 9, wherein the chemical solution is isopropyl alcohol (IPA).
